(19) United States
(12) Patent Application Publication
(10) Pub. No.: US 2026/0132509 A1
(43) Pub. Date: May 14, 2026

(54) AMPOULE FOR A SEMICONDUCTOR MANUFACTURING PRECURSOR

(71) Applicant: Applied Materials, Inc., Santa Clara, CA (US)

(72) Inventor: Muhannad Mustafa, Milpitas, CA (US)

(73) Assignee: Applied Materials, Inc., Santa Clara, CA (US)

(21) Appl. No.: 18/886,442

(22) Filed: Sep. 16, 2024

(51) Int. Cl. C23C 16/455; C23C 16/448

(52) U.S. Cl. CPC C23C 16/45561; C23C 16/4481

(57) ABSTRACT

Ampoules for precursors include a cavity, an outlet port, an inlet port configured to be connected to a carrier gas supply. The inlet port has an inlet conduit having a length extending into the cavity and defining a passageway. Gas openings along the length of the conduit are spaced at a distance that increases from the outlet port. The gas openings have an area that incrementally increases as the distance from the gas outlet port increases and the gas openings are configured to direct the flow the carrier gas parallel to a surface of the precursor contained in the cavity. A float within the passageway blocks carrier gas flow through the passageway and move away from the outlet port as a volume of the precursor in the ampoule decreases and to direct the carrier gas through one or more of the gas openings above the float.

### TECHNICAL FIELD

The present disclosure relates generally to ampoules for semiconductor manufacturing precursors and methods of delivering semiconductor manufacturing precursors to semiconductor processing chambers. In specific embodiments, the disclosure relates to ampoules and methods to provide full saturation of the carrier gas with precursor regardless precursor headspace inside ampoule.

### BACKGROUND

The semiconductor industry is using an increasing variety of liquid and solid precursors, also referred to as “chemistries,” for chemical vapor deposition (CVD) and atomic layer deposition (ALD) processes. The precursor or chemistry is typically inside a closed vessel or an ampoule with a single inlet and a single outlet, and the precursor is typically delivered to a semiconductor process chamber as a vapor using a carrier gas.

Precursors with a low vapor pressure typically utilize the carrier gas to carry the precursor vapor out of the ampoule to the semiconductor process chamber in vapor deposition processes. These types of processes typically use two types of ampoules: a bubbler in which the inlet carrier gas goes into a tube that is submerged into the precursor; and a cross-flow ampoule where the carrier gas sweeps headspace in the ampoule. Often, there is only a very short flow path for the carrier gas to entrain vapor. The short flow path from the inlet to the outlet of the vessel does not allow adequate residence time within the vessel to allow the carrier gas to become fully saturated with vaporized or sublimed precursor. Some existing ampoule designs do not evenly distribute the carrier gas across the entire surface of the precursor. A single gas opening injector ampoule cannot be run at full saturation with a higher headspace as the precursor is depleted from the ampoule, but a multiple gas opening injector ampoule (or showerhead ampoule) has an advantage of running at full saturation. However, due to a jet effect, a particle generation issue is a concern for showerhead ampoules. Temperature optimization is another option to adjust vapor pressure to ensure consistent precursor flux from a single gas opening injector. But temperature optimization is time-consuming and often involves a trial and error approach to optimize to ensure consistent precursor flux.

There is a need in the art for ampoules and methods of providing a flow of precursor in a substrate processing chamber during a vapor deposition process to form a film on a substrate, where the ampoule provides for nearly full or full saturation of the carrier gas with the precursor and to provide consistent delivery of the precursor.

### SUMMARY

One or more embodiments are directed to an ampoule configured to deliver a semiconductor manufacturing precursor to a substrate processing chamber. The ampoule comprises a container defining a cavity configured to hold the precursor, the container defined by sidewalls, a bottom wall and a lid; an outlet port in fluid communication with the cavity and configured for connection to a conduit to deliver a gaseous precursor to the substrate processing chamber; an inlet port in fluid communication with the cavity and configured to be connected to a carrier gas supply, the inlet port comprising an inlet conduit having a length extending into the cavity and defining a passageway; gas openings along the length of the conduit that are spaced at a distance that increases from the outlet port, wherein each of the gas openings have an area that incrementally increases as the distance each of the gas openings from the gas outlet port increases and each of the gas openings is configured to direct a flow of the carrier gas parallel to a surface of the precursor contained in the cavity; and a float movably disposed within the passageway, the float configured to block carrier gas flow through the passageway and move away from the outlet port as a volume of the precursor in the ampoule decreases and to direct the carrier gas through one or more of the gas openings above the float.

Further embodiments of the disclosure are directed to of providing a flow of precursor to a substrate processing chamber during a vapor deposition process to form a film on a substrate, the method comprising flowing a carrier gas through the ampoule described herein, wherein the ampoule contains a liquid precursor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure, and are therefore not to be considered limiting of its scope, for the disclosure may admit to other equally effective embodiments.

FIG. 1 is an isometric view of an ampoule in accordance with one or more embodiments;

FIG. 2 is a cross-sectional view of the ampoule in FIG. 1 in accordance with one or more embodiments;

FIG. 3 is an isometric cross-sectional view of the ampoule in FIG. 1 in accordance with one or more embodiments;

FIG. 4 is a partial cross-sectional view of the ampoule in FIG. 1 in accordance with one or more embodiments; and

FIG. 5 is a cross-sectional view of an alternative embodiment of an ampoule in accordance with one or more embodiments;

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label. The cross-hatched shading of the components in the figures are intended to aid in visualization of different parts and do not necessarily indicate different materials of construction.

### DETAILED DESCRIPTION

Before describing several exemplary embodiments of the disclosure, it is to be understood that the disclosure is not limited to the details of construction or process steps set forth in the following description. The claimed ampoules and methods are capable of other embodiments and of being practiced or being carried out in various ways.

One or more embodiments of the disclosure advantageously provide an ampoule that runs at or close to a vapor saturation condition even as the headspace above the precursor level in the ampoule decreases as the precursor is consumed in during a substrate processing operation in a substrate processing chamber. In some embodiments, a carrier gas is used to precursor from an ampoule to a substrate processing chamber. In specific embodiments, the precursor is a liquid precursor.

In one or more embodiments, a carrier gas is directed substantially horizontally across the ampoule so that that carrier gas sweeps the headspace parallel to the liquid precursor in the ampoule. Advantageously, saturation efficiency of the vaporized precursor in the carrier gas is improved. Reference herein to “saturated” allows for varying degrees of saturation. In one or more embodiments, the carrier gas is fully saturated with the vaporized precursor, and the degree of saturation of the precursor in the carrier gas remains substantially constant as the amount of precursor decreases in the ampoule and the volume of the headspace increases. As used herein, “substantially constant” refers to the degree of saturation as varying less than 5%, less than 4%, less than 3%, less than 2%, less than 1%, less than 0.5% or less than 0.1% from when the ampoule is filled with precursor to where the precursor volume in the ampoule is reduced to 25%, 20%, 15% or 10% of the original volume of the precursors when the ampoule is full.

Generally, according to one or more embodiments, an ampoule comprises a container defining a cavity configured to hold and contain a precursor, and in particular embodiments, a liquid precursor. There is a space between the uppermost level of the precursor and the top of the ampoule, which is usually a lid called the headspace. The ampoule generally includes an inlet port and an outlet port, both in fluid communication with the cavity.

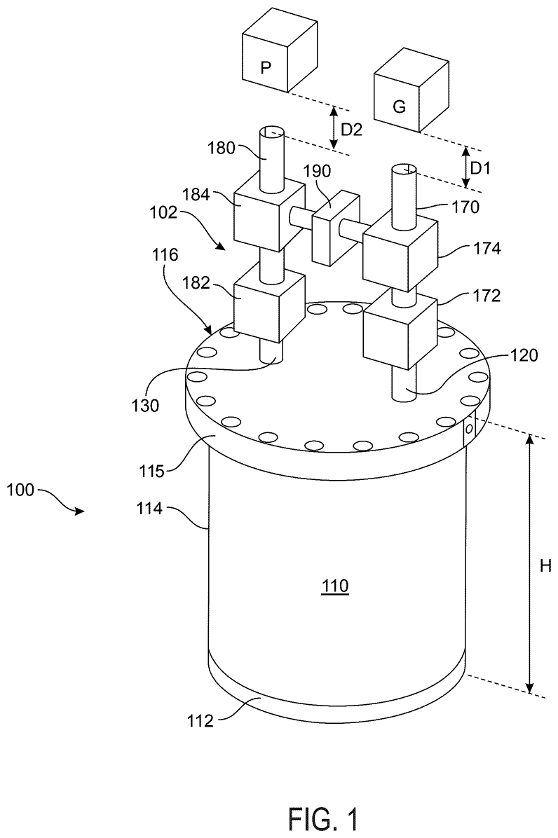

FIG. 1 shows an isometric view of an ampoule 100 in accordance with one or more embodiments. The ampoule 100 is configured to deliver a semiconductor manufacturing precursor to a substrate processing chamber. The ampoule 100 and a gas manifold 102 are suitable for use with semiconductor manufacturing raw materials, which include reagents and precursors. The term “precursor” is used to describe the contents of the ampoule 100 and refers to any reagent that flows into a process environment, in particular, a substrate processing chamber. In specific embodiments, the precursors are liquid precursors that are delivered as vapors to a substrate processing chamber to form films on a substrate, including, but not limited to silicon films, metal films and dielectric films.

The ampoule 100 comprises a container 110 including a bottom wall 112, sidewalls 114, and a lid assembly 116 including a lid 115. The lid has a bottom surface 115b. An inlet port 120 and outlet port 130 are in fluid communication with a cavity 109 defined by internal walls of the container 110. The inlet port 120 is generally configured to allow a connection to a gas source “G” spaced at a distance “D” from the gas manifold 102 by way of suitable piping and valve(s) and may have suitable threaded or sealing connections. In one or more embodiments, the gas source “G” is a carrier gas. In one or more embodiments, the carrier gas is air or an inert gas such as nitrogen, argon, helium, hydrogen and mixtures thereof. In some embodiments, the carrier gas may contain oxygen and/or nitrogen.

The outlet port 130 is also in fluid communication with the cavity. The outlet port 130 is generally configured to be able to connect to a conduit or a line, including suitable piping and valve(s), to allow the flow of gases, which may include entrained vapor and/or particles, exiting the container 110 to flow to a processing chamber (or other component) “P”. The processing chamber “P” is spaced at a distance “D2” from the gas manifold 102. The outlet port 130 may have a welded or threaded connection to allow a gas line to be connected. A height (H) of the cavity defined by the container 110 spans from a lower surface 116a of the lid assembly 116 to a top surface 112a of the bottom wall 112.

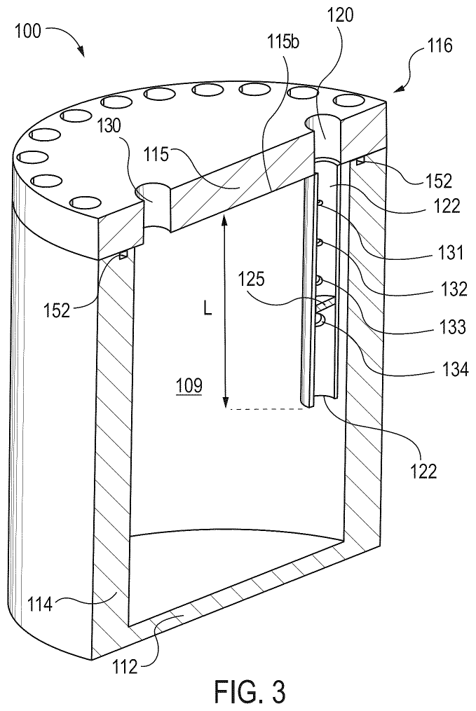

The inlet port 120 has a passageway 121 with an inner diameter defining a cross-sectional width of the passageway 121 connected to a conduit 122 having a length “L” (shown in FIG. 3) that extends into a portion of the container 110 from the bottom surface 115b of the lid 115 of the lid assembly 116. A volume of incoming carrier gas from a source “G”, flows into the cavity 109 of the ampoule 100. In one or more embodiments, the inlet port passageway 121 comprises a single gas opening as shown.

The outlet port 130 has a passageway 130p with an inner diameter defining a cross-sectional width of the passageway 130p. The outlet port passageway 130p is designed to accommodate a volume of outgoing entrained and/or saturated carrier gas, which in turn flows out of the ampoule to a downstream process chamber “P”.

Different manifold configurations can be connected to the lid assembly 116 to allow the ampoule 100 to be added to a process chamber. In some embodiments, the inlet line 170 is connected to the inlet port 120. An inlet valve 172 can be positioned on the inlet line 170 between gas source “G” and the inlet port 120. The inlet valve 172 can be integrally formed with the lid assembly 116 or connected to the lid assembly 116 as a separate component. An outlet line 180 can be connected to the outlet port 130. The outlet line 180 of some embodiments includes an outlet valve 182 located between the outlet port 130 and the processing chamber “P”. The inlet valve 172 and outlet valve 182 can be used to isolate the ampoule 100 so that the contents of the cavity 109 are isolated from the environment outside of the container 110. In some embodiments, there are multiple valves along the inlet line 170 (e.g., second inlet valve 174) and/or the outlet line 180 (e.g., second outlet valve 184) and/or therebetween (e.g., auxiliary valve 190). Each of these aforementioned valves can be manual valves or pneumatic valves.

In some embodiments, the lid assembly 116 is a separate component from the bottom wall 112 and sidewalls 114. The lid assembly 116 can be connected to the sidewalls 114 of the container 110 using removable bolts (not shown) through a plurality of threaded openings 101, which may have a threaded portion to allow for easy connection of a threaded bolt. The removable bolts can be removed to allow the lid assembly 116 to be removed from the container 110 so that the precursor 150 in the container 110 can be changed or added.

In some embodiments, the lid 115 includes the plurality of threaded openings 101 to receive fasteners such as the removeable bolts (not shown) or other suitable fasteners to secure the lid 115 to the container 110. A first seal 152 is located between an upper surface of the sidewalls 114 and the bottom surface 115b of the lid 115 to form a fluid tight seal. In embodiments in which the bottom wall 112 is a separately formed element, a second seal is located between an upper portion of the bottom wall 112 and a lower surface of the sidewalls 114 to form a fluid tight seal. In the embodiment shown, the bottom wall 112 is integrally formed with the sidewalls 114, eliminating the need for a second seal. In some embodiments where the bottom wall 112 is a separately formed element, the first seal 152 and the second seal are independently an O-ring. In some embodiments (not shown), the lid assembly 116 can be integrally formed with the sidewalls 114 and the bottom wall 112 of the container 110.

Thermocouples, mass flow meters, and pressure gauges may be included in the equipment denoted herein in order to monitor process conditions. In one or more embodiments, a mass flow meter is provided to monitor gas flow into the inlet port. In one or more embodiments, a thermocouple is installed in the lid assembly. In one or more embodiments, a pressure gauge is provided on the inlet line and/or the outlet line. A pressure range within the ampoule in accordance with some embodiments is greater than or equal to 25 torr to less than or equal to 150 torr.

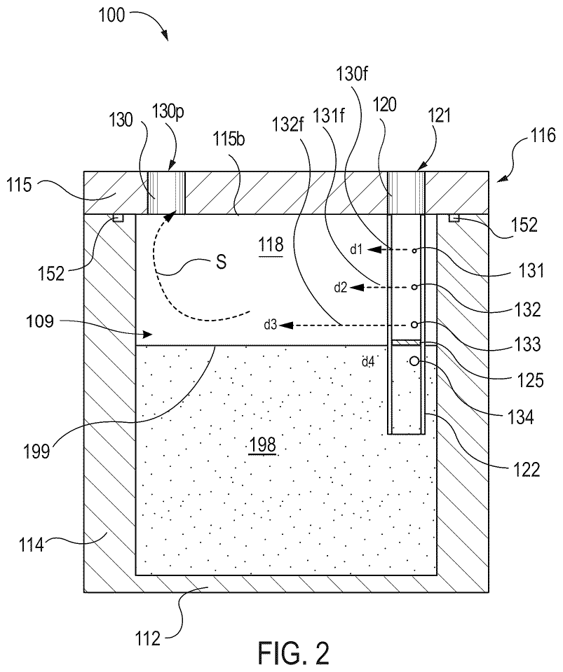

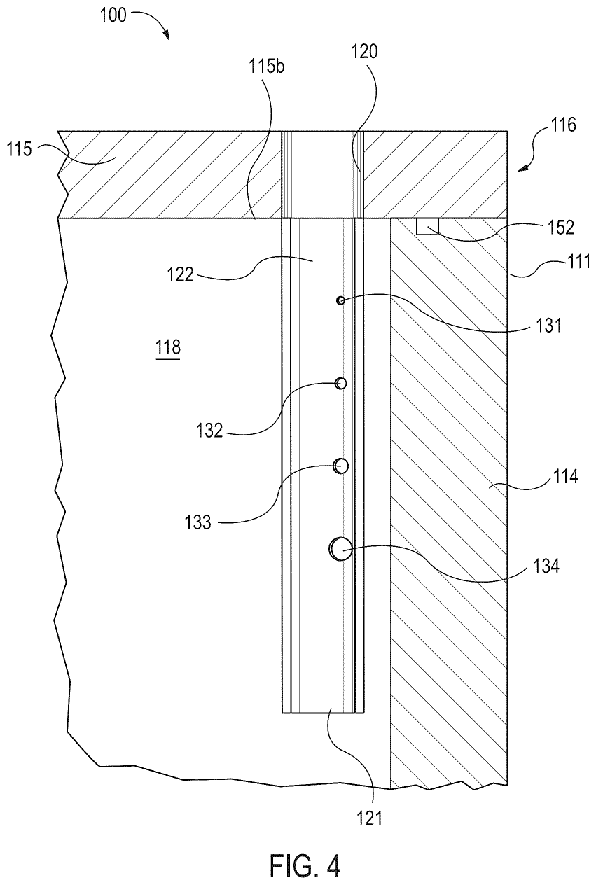

Specifically referring now to FIGS. 2-4, an ampoule 100 configured to deliver a semiconductor manufacturing precursor 198 to a substrate processing comprises the container 110 defining a cavity 109 configured to hold the precursor, the container defined by the sidewalls 114, the bottom wall 112 and a lid 115. The outlet port 130 is in fluid communication with the cavity 109 and configured for connection to a conduit to deliver a gaseous precursor to the substrate processing chamber “P”. The ampoule 100 further includes an inlet port 120 in fluid communication with the cavity 109 and configured to be connected to a carrier gas supply “G”, the inlet port comprising an inlet conduit 122 having a length “L” extending into the cavity 109 and defining a passageway 121 for the carrier gas to be delivered into the cavity 109.

The conduit 122 includes gas openings along the length “L” of the conduit 122 that are spaced at a distance that increases from the outlet port 130. More specifically, the distance each of gas openings are spaced vertically from the outlet port, which extends from the bottom surface 115b of the lid 115. It will be understood that in some embodiments, the outlet port 130 may be in a location other than in the lid 115. For example, the outlet port 130 according to some embodiments may be in the sidewall 114 of the container 110.

In the embodiment shown, there is a first gas opening 131 that is spaced a first distance 31 from the outlet port 130, which located at the underside of the lid 115. A second gas opening 132 is spaced at a second distance d2 that is greater than the first distance 1. There is a third gas opening 133 that is spaced at a third distance d3 greater than the second distance, and a fourth gas opening 134 spaced at a distance d4 greater than the third distance. Thus, the gas openings 131, 132, 133, and 134 are incrementally spaced at increasing distances from the outlet port 130 on the bottom surface 115b of the lid 115.

Furthermore, each of the first gas opening 131, the second gas opening 132, the third gas opening 133 and the fourth gas opening 134 have an area that incrementally increases as the distance of the respective gas openings, namely the first gas opening 131, the second gas opening 132, the third gas opening 133 and the fourth gas opening 134 from the gas outlet port 130 increases. In other words, gas opening 130 is at a distance d1 that is less than the distance d2 of the second gas opening 132, which is less than the distance d3 of the third gas opening 133, which is less than the distance d4 of the fourth gas opening 134. Each of the first gas opening 131, the second gas opening 132, the third gas opening 133 and the fourth gas opening 134 is configured to direct a flow of the carrier gas parallel to a surface 199 of the precursor 198 contained in the cavity 109.

As seen in FIG. 2, gas opening 130 has a small diameter and a gas flow 130f of the carrier gas “G” that is substantially parallel to the surface 199 of the precursor 198 int he container. As used herein, “parallel” refers to within 5 degrees, within 4 degrees, within 3 degrees, within 2 degrees, within 1 degree and exactly 180 degrees with respect to the surface 199 of the precursor 198.

The ampoule 100 of the present disclosure further comprises a float 125 movably disposed within the passageway 121. The float 125 is configured to block carrier gas “G” flow through the passageway 121 and move away from the outlet port 130 as a volume of the precursor 198 in the ampoule decreases and to direct the carrier gas through one or more of the gas openings above the float 125, namely, the first gas opening 131, the second gas opening 132, the third gas opening 133 and the fourth gas opening 134.

When the ampoule 100 is full of precursor 198, the surface 199 of the precursor will be above the fourth gas opening 134, the third gas opening 133, and the second gas opening 132. Thus, as carrier gas “G” is delivered through the inlet port 120 the carrier gas “G” will be delivered through the first gas opening 131 to provide a gas flow 130f. It will be appreciated that the headspace 118, which is the distance between the surface 199 of the precursor 198 and the bottom surface 115b of the lid 115 will be relatively small compared to the distance when the precursor 198 is consumed during a substrate processing operation.

Thus, as the precursor is consumed and the surface 199 of the precursor 198 decreases, the head space will increase. When the surface 199 of the precursor 198 drops will the second opening, the float 125 will block the carrier gas “G” from flowing through the third gas opening 133 and the fourth gas opening 134. As specifically shown in FIG. 2, the float 125 is supported by the surface 199 of the precursor 198 above the fourth gas opening 134 so that the float 125 blocks the flow of carrier gas “G” from flowing through the fourth gas opening 134, but the carrier gas “G” flows through the first gas opening 131, the second gas opening 132 and the third gas opening 133. There is a gas flow 130f of gas from the first gas opening 131, a flow of gas 131f from the second gas opening 132, and a flow of gas flow 132f from the third gas opening 133. The gas flow 130f, 131f and 132f are each substantially parallel to the surface 199 of the precursor 198.

In a single opening inlet port 120 of the type shown in FIGS. 2-5, previously, it was observed to be difficult to maintain a constant gas conductance and saturation of the precursor in the carrier gas. Advantageously, according to one or more embodiments, the conduit 122, including the flat and three or more gas openings spaced along the length of the conduit provides an ampoule in which the degree of saturation of the precursor in the carrier gas remains substantially constant as the amount of precursor 198 decreases in the ampoule and the volume of the headspace 118 increases.

Thus, the first gas opening 131 at the first distance d1 closest to the outlet port 130 is configured to allow a first gas flow conductance C1, the second gas opening 132 at a second distance d2 further from the outlet port 130 than the first distance d1 and is configured to allow a second gas flow conductance C2, and the third gas opening 133 is at a third distance d3 further from the outlet port 130 than the second distance d2 and is configured to allow a gas flow conductance C3. Advantageously, the first gas flow conductance C1, the second gas flow conductance C2 and the third gas flow conductance C3 are such that C1/C2 is equal to (C1+C2)/C3.

As shown in FIGS. 2-4, there is a single gas opening at each of the first distance d1, the second distance d2, and the third distance d3. In specific embodiments, there is only a single opening at each of d1, d2 and d3. As shown there is first single gas opening 130 at the first distance d1, which has a first diameter, a second single gas opening 131 at the second distance d2 which has a second diameter and a third single gas opening 133 at the third distance d3 which has a third diameter. The third diameter is greater than the second diameter than the second diameter, and the second diameter is greater than the first diameter.

In the embodiment shown, there is a fourth single gas opening 134 at a fourth distance d4 further from the outlet port 130 than the third distance d3, which is configured to allow a fourth gas flow conductance C4. In this embodiment, C1/C2 is equal to (C1+C2+C3)/C4. Each of C1, C2 and C3 are configured to deliver precursor to the outlet at or near saturation. The conductance C1, C2, C3 and C4 each is configured to deliver precursor to the outlet at or near saturation of the precursor in the carrier gas, which will depend on the carrier gas and the precursor. The degree of saturation of the precursor in the carrier gas remains substantially constant as the amount of precursor decreases in the ampoule at each of the distances d1, d2, d3 and d4.

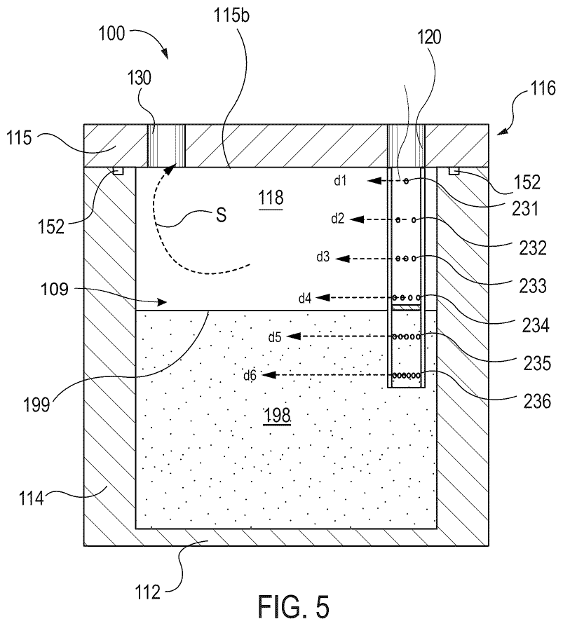

FIG. 5 shows an embodiment in which there is a single gas opening 231 at the first distance d1 configured to allow a first gas flow conductance C1, two or more gas openings 232at the second distance d2 configured to allow a second gas flow conductance C2, and three or more gas openings 233 at the third distance d3 configured to allow a third gas flow conductance C3 such that C1/C2 is equal to (C1+C2)/C3.

Also shown in FIG. 5, there are four or more gas openings 234 at a fourth distance d4 greater than the third distance d3 and configured to allow a fourth gas flow conductance C4such that C1/C2 is equal to (C1+C2+C3)/C4. In the embodiment shown, the single gas opening 231 at the first distance d1, the two or more gas openings 232 at the second distance d2 and the three or more gas openings 233 at the third distance d3 each have an equal diameter to the other gas openings at the different distances d1, d2, and d3. Similarly, the four of more gas openings 234 at the fourth distance d4 have an equal diameter equal to the diameter of the single gas opening 231, the two or more gas openings 233, and the three or more gas openings 233.

At distance d5, there are five or more gas openings 235, and at distance d6, there are six or more gas openings 236. As with the above description, in the embodiment shown, each of the five or more gas openings 235 have the same diameter as each of the six or more gas openings 236, and the gas openings at each of d1, d2, d3, and d4. The conductance at C5 and C6 is configured so that the degree of saturation of the precursor in the carrier gas remains substantially constant as the amount of precursor decreases in the ampoule at each of the distances d1, d2, d3, d4, d5 and d6.

It will be appreciated that at each of the respective distances in d1, d2, d3 and d4 and FIGS. 2-4 the conductance is controlled by changing the diameter of the single gas opening at each level. However, in the embodiment in FIG. 5, the area is increased as the distance from the outlet port 130 increases by increasing the number of gas openings at d1, d2, d3, d4, d5 and d6.

While the claims are not to be limited by any theory of operation, in embodiments in which the diameter of the gas openings is changed at different distances from the gas outlet port, the following equation may be used for gas flow conductance (C) and d is the diameter of the gas opening.

$$C = ( 256 / η ) * {d}^{4} / L * ( P 1 + P2 ) where C = f ( {d}^{4} ) . \qquad ( Equation 1 )$$

Thus, according to one or more embodiments, the gas opening size increases incremental way so that agas flow conductance ratio of each level i is constant according to the formula Ci/Ci+1. The variable η is the number of holes and Ci indicates the overall conductance above Ci+1th gas opening. Therefore, a primary gas opening conductance will always be closer to the precursor surface. The float 125 will stay at the level of the precursor surface 199 and prevent any carrier gas flow to precursor directly through the conduit. Since the primary conductance always remains closer to the surface to maintain a similar conductance ratio, the same mass fraction of carrier gas will flow through last gas openings. A gas flow rate will also be maximum through the last gas opening. With increasing headspace 118, the float 125 will travel downwardly, and maximum carrier gas will flow through the last gas opening to draw vapor shown as “S” in FIG. 2. However, closer to the precursor surface 199, the vapor concentration will be close to full saturation. Therefore, ampoule saturation efficiency will remain substantially constant as the headspace increases as the level of precursor in the ampoule decreases.

Another aspect of the disclosure pertains to a method of providing a flow of precursor to a substrate processing chamber during a vapor deposition process to form a film on a substrate and maintaining a substantially constant degree of saturation of the precursor in a carrier gas. The method comprising varying the conductance of gas flowing across the headspace of the precursor surface as the amount of precursors in the ampoule decreases. In some embodiments, the method comprising flowing a carrier gas through the ampoule described herein, wherein the ampoule contains a liquid precursor.

The method further comprises delivering the precursor through the outlet port. In some embodiments of the method, there is a first gas opening at a first distance closest to the outlet port configured to allow a first gas flow conductance C1, a second gas opening at a second distance further from the outlet port than the first distance and configured to allow a second gas flow conductance C2, and a third gas opening at a third distance further from the outlet port than the second distance configured to allow a gas flow conductance C3.

In some embodiments, when the ampoule is full of the liquid precursor, the float is positioned below the first gas opening and above the second gas opening. In some embodiments, as the liquid precursor is consumed by the vapor deposition process, the float moves below the second gas opening In some embodiments, as the precursor is further consumed by the vapor deposition process, the float moves below the third gas opening.

In one or more embodiments, C1/C2 is equal to (C1+C2)/C3. In some embodiments, as the liquid precursor is consumed by the vapor deposition process, wherein there is a fourth gas opening at a fourth distance from the further from the outlet port than the third distance configured to allow a fourth gas flow conductance C4, and wherein C1/C2 is equal to (C1+C2+C3)/C4. In some method embodiments, the first gas opening, the second gas opening, the third gas opening and the fourth gas opening are configured to deliver the liquid precursor to the outlet as a vapor at saturation. In one or more method embodiments, there is a headspace above the liquid precursor and the liquid precursor is consumed, delivery efficiency of the ampoule remains equal as the headspace increases.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. An ampoule configured to deliver a semiconductor manufacturing precursor to a substrate processing chamber, the ampoule comprising:
a container defining a cavity configured to hold the precursor, the container defined by sidewalls, a bottom wall and a lid;
an outlet port in fluid communication with the cavity and configured for connection to a conduit to deliver a gaseous precursor to the substrate processing chamber;
an inlet port in fluid communication with the cavity and configured to be connected to a carrier gas supply, the inlet port comprising an inlet conduit having a length extending into the cavity and defining a passageway;
gas openings along the length of the conduit that are spaced at a distance that increases from the outlet port, wherein each of the gas openings have an area that incrementally increases as the distance of each of the gas openings from the gas outlet port increases and each of the gas openings is configured to direct a flow of the carrier gas parallel to a surface of the precursor contained in the cavity; and
a float movably disposed within the passageway, the float configured to block carrier gas flow through the passageway and move away from the outlet port as a volume of the precursor in the ampoule decreases and to direct the carrier gas through one or more of the gas openings above the float.

2. The ampoule of claim 1, wherein there is a first gas opening at a first distance closest to the outlet port configured to allow a first gas flow conductance C1, a second gas opening at a second distance further from the outlet port than the first distance and configured to allow a second gas flow conductance C2, and a third gas opening at a third distance further from the outlet port than the second distance configured to allow a gas flow conductance C3, wherein the first gas flow conductance, the second gas flow conductance and the third gas flow conductance are such that C1/C2 is equal to (C1+C2)/C3.

3. The ampoule of claim 2, wherein there is a single gas opening at each of the first distance, the second distance and the third distance.

4. The ampoule of claim 3, wherein there is a first single gas opening at the first distance has a first diameter, a second single gas opening at the second distance has a second diameter and a third single gas opening at the third distance has a third diameter, and the third diameter is greater than the second diameter than the second diameter, and the second diameter is greater than the first diameter.

5. The ampoule of claim 4, wherein a fourth single gas opening at a fourth distance further from the outlet port than the third distance configured to allow a fourth gas flow conductance C4, and wherein C1/C2 is equal to (C1+C2+C3)/C4.

6. The ampoule of claim 1, wherein C1, C2 and C3 are configured to deliver precursor to the outlet at or near saturation.

7. The ampoule of claim 5, wherein C1, C2, C3 and C4 are configured to deliver precursor to the outlet at or near saturation.

8. The ampoule of claim 2, wherein there is a single gas opening at the first distance configured to allow a first gas flow conductance C1, two or more gas openings at the second distance configured to allow a second gas flow conductance C2, and three or more gas openings at the third distance configured to allow a third gas flow conductance C3 such that C1/C2 is equal to (C1+C2)/C3.

9. The ampoule of claim 8, wherein there are four or more gas openings at a fourth distance greater than the third distance and configured to allow a fourth gas flow conductance C4 such that C1/C2 is equal to (C1+C2+C3)/C4.

10. The ampoule of claim 8, wherein the single gas opening at the first distance, the two or more gas openings at the second distance and the three or more gas openings at the third distance each have an equal diameter.

11. A method of providing a flow of precursor to a substrate processing chamber during a vapor deposition process to form a film on a substrate, the method comprising flowing a carrier gas through the ampoule of claim 1, wherein the ampoule contains a liquid precursor.

12. The method of claim 11, further comprising delivering the precursor through the outlet port.

13. The method of claim 12 wherein there is a first gas opening at a first distance closest to the outlet port configured to allow a first gas flow conductance C1, a second gas opening at a second distance further from the outlet port than the first distance and configured to allow a second gas flow conductance C2, and a third gas opening at a third distance further from the outlet port than the second distance configured to allow a gas flow conductance C3.

14. The method of claim 13, wherein when the ampoule is full of the liquid precursor, the float is positioned below the first gas opening and above the second gas opening.

15. The method of claim 14, wherein as the liquid precursor is consumed by the vapor deposition process, the float moves below the second gas opening.

16. The method of claim 14, wherein as the precursor is further consumed by the vapor deposition process, the float moves below the third gas opening.

17. The method of claim 16, wherein C1/C2 is equal to (C1+C2)/C3.

18. The method of claim 17, wherein as the liquid precursor is consumed by the vapor deposition process, wherein there is a fourth gas opening at a fourth distance from the further from the outlet port than the third distance configured to allow a fourth gas flow conductance C4, and wherein C1/C2 is equal to (C1+C2+C3)/C4.

19. The method of claim 17, wherein the first gas opening, the second gas opening, the third gas opening and the fourth gas opening are configured to deliver the liquid precursor to the outlet as a vapor at saturation.

20. The method of claim 11, wherein there is a headspace above the liquid precursor and the liquid precursor is consumed, delivery efficiency of the ampoule remains equal as the headspace increases.
